(19) United States
(12) Patent Application Publication
(10) Pub. No.: US 2005/0230805 A1
(43) Pub. Date: Oct. 20, 2005

(54) Semiconductor device, method for producing the same, circuit board, and electronic apparatus

(76) Inventor: Ikuya Miyazawa, Matsumoto (JP)

Correspondence Address: HARNESS, DICKEY & PIERCE, P.L.C., P.O. BOX 828, BLOOMFIELD HILLS, MI, 48303, US

(21) Appl. No.: 11/105,965

(22) Filed: Apr. 14, 2005

(30) Foreign Application Priority Data
Apr. 16, 2004 (JP) 2004-121646

(51) Int. Cl. H01L 27/01

(52) U.S. Cl. 257/690

(57) ABSTRACT

A method for making a semiconductor device having an electrode penetrating a substrate includes (a) forming a concavity in an active face of the substrate; (b) forming an insulating layer on the active face of the substrate and the interior of the concavity; (c) removing at least part of the insulating layer formed outside the concavity; (d) forming the electrode by filling the interior of the concavity with a conductor; and (e) exposing the electrode from a rear face of the substrate opposite to the active face by milling the substrate from the rear face side. In this method, (a) to (e) are performed in that order.

### RELATED APPLICATIONS

This application claims priority to Japanese Patent Application No. 2004-121646 filed Apr. 16, 2004 which is hereby expressly incorporated by reference herein in its entirety.

### BACKGROUND OF THE INVENTION

1. Technical Field

The present invention relates to semiconductor devices, methods for making the semiconductor devices, circuit boards, and electronic apparatuses.

2. Related Art

Demands for smaller, light-weight portable electronic apparatuses, such as cellular phones, portable personal computers, and personal data assistances (PDAs), also require various electronic components in these apparatuses to achieve size reduction. For example, the technique of packaging semiconductor chips has been improved, and now an ultra compact packaging technique called chip scale packaging (CSP) is available. Semiconductor chips produced by the CSP technique achieves high-density mounting since the mount area is about the same as the area of the semiconductor chips.

Demands for further size reduction and achievement of more diverse performance on these electronic apparatuses are expected to continue; thus, the mount density of semiconductor chips needs to be increased further. Recently, three-dimensional mounting has been proposed to meet such demands. According to this three-dimensional mounting technique, semiconductor chips having similar or different functions are stacked and interconnected to each other to achieve high-density mount (refer to Japanese Unexamined Patent Application Publication No. 2001-53218).

According to the three-dimensional mounting technique, semiconductor chips are electrically connected to one another via electrodes that fill through holes formed in the semiconductor chips. Insulating layers are disposed on active faces of the semiconductor chips and inner walls of the through holes, thereby providing insulation of the interiors of the through holes and protecting the electrode terminals formed on rear faces of the semiconductor chips.

However, the substrates of the semiconductor chips have different physical constants, i.e., a thermal expansion coefficient and an internal stress, from those of the insulating layers. Moreover, the insulating layers are formed on only active faces of the substrates in which integral circuits are formed. Thus, when these semiconductor chips are assembled into one chip, stresses are generated in the substrates due to the difference in internal stress and the like between the substrates and the insulating layers. As a result, the substrates deform and warp due to the stress. The warpage in the substrates makes it difficult to mount the semiconductor chips on a wiring board or the like. Furthermore, as is described above, when semiconductor chips are stacked on one another to achieve three-dimensional mounting, the active face (i.e., the face in which an integral circuit is formed) or the rear face of the semiconductor chip becomes curved. Thus, sometimes it is difficult to stack the semiconductor chips and to provide electrical or mechanical interconnection between the semiconductor chips and the electrodes.

### SUMMARY

An advantage of the invention is to provide a semiconductor device in which the warpage of substrates caused by the difference in stress between the substrates and functional layers formed on the substrates is eliminated or minimized, and a method for making the semiconductor device. A circuit board and an electronic apparatus incorporating the semiconductor device are also provided.

An aspect of the invention provides a method for making a semiconductor device having an electrode penetrating a substrate. The method includes (a) forming a concavity in an active face of the substrate; (b) forming an insulating layer on the active face of the substrate and the interior of the concavity; (c) removing at least part of the insulating layer formed outside the concavity; (d) forming the electrode by filling the interior of the concavity with a conductor; and (e) exposing the electrode from a rear face of the substrate opposite to the active face by milling the substrate from the rear face side. The steps (a) to (e) are performed in that order.

According to this method, the internal stress or thermal expansion coefficient of the insulating layer can be eliminated or minimized during the process of removing the insulating layer on the active face of the substrate. Thus, the internal stress or thermal expansion coefficient of the insulating layer acting upon the substrate can be eliminated or minimized. The difference in internal stress or thermal expansion coefficient between the substrate and the insulating layer can also be reduced. Thus, warpage of the substrate can be prevented. When a plurality of the semiconductor devices are stacked, an adhesive free of conductive particles, a reinforcing member, or the like is placed between the adjacent semiconductor devices to ensure insulation between the semiconductor devices. Thus, even when the insulating layer formed on the active face of the substrate is removed, troubles will not occur because of the adhesive or the like having an insulating function.

In the step (c) above, the insulating layer may be etched while covering the concavity with a mask to protect the insulating layer inside the concavity from an etchant. In this manner, it becomes possible to prevent removal of the insulating layer inside the concavity.

In step (c), the entire face of the insulating layer may be etched while adjusting the etching rate of the insulating layer formed on the substrate to be higher than the etching rate of the insulating layer formed on the interior of the concavity in the substrate. In this manner, the insulating layers on the substrate can be removed without affecting the insulating layer inside the concavity. Moreover, since a step of forming a mask is no longer necessary, the process is simple, and the time required for production can be reduced.

Another aspect of the invention provides a method for making a semiconductor device having an electrode penetrating a substrate. The method includes (f) forming a concavity in an active face of the substrate; (g) forming an insulating layer on the active face of the substrate and interior of the concavity; (h) forming the electrode by filling the interior of the concavity with a conductor; (i) removing at least a portion of the insulating layer outside the concavity; and (j) exposing the electrode from a rear face of the substrate opposite to the active face by milling the substrate from the rear face side. In this method, the steps (f) to (j) are performed in that order.

According to this method, the internal stress or thermal expansion coefficient of the insulating layer can be eliminated or minimized since the insulating layer on the active face of the substrate is removed. Thus, the internal stress or thermal expansion coefficient of the insulating layer acting upon the substrate can be eliminated or minimized. The difference in internal stress or thermal expansion coefficient between the substrate and the insulating layer can also be reduced. Thus, warpage of the substrate can be prevented.

In the step (i), the insulating layer may be etched while covering the concavity with a mask to protect the surface of the exposed electrode from an etchant. Thus, it becomes possible to prevent the electrode from being etched.

Preferably, in the step (i), the insulating layer is etched while covering the concavity with a bonding member. The bonding member may be composed of a lead-free solder, anisotropic conductive paste (ACP), an anisotropic conductive film (ACF), a non-conductive film (NCF), or the like. When a plurality of the semiconductor devices are stacked to achieve multilevel wiring, the bonding member electrically connects the electrodes of the semiconductor devices to each other. Because the bonding member is used as a mask for etching the insulating layer, it becomes possible to omit a photolithographic step of patterning a resist.

A yet another aspect of the invention provides a semiconductor device including a substrate having an active face including an integrated circuit, a rear face, and a hole penetrating the substrate from the active face to the rear face; an insulating layer disposed on the active face of the substrate and on an inner wall of the hole; and an electrode disposed inside the space defined by the insulating layer. The electrode is exposed from the rear face of the substrate. A portion of the insulating layer on the active face of the substrate has a thickness smaller than the thickness of a portion of the insulating layer at the periphery of the electrode.

Because the thickness of the portion of the insulating layer on the active face of the substrate is smaller than the thickness of the portion of the insulating layer at the periphery of the electrode, short-circuiting can be prevented by the portion of the insulating layer at the periphery of the electrode. At the same time, it becomes possible to reduce the internal stress or the thermal expansion coefficient of the insulating layer on the active face of the substrate. Thus, the difference in internal stress or thermal expansion coefficient between the substrate and the insulating layer can be minimized, and warpage of the substrate can be suppressed.

A still another aspect of the invention provides a semiconductor device including a substrate having an active face including an integrated circuit, a rear face, and a hole penetrating the substrate from the active face to the rear face; an insulating layer disposed on an inner wall of the hole; and an electrode disposed inside the space defined by the insulating layer, the electrode being exposed from the rear face. According to this structure, the insulating layer is not formed on the active face of the substrate, or the insulating layer is formed only on part of the active face of the substrate. Thus, short-circuiting or the like can be prevented by the insulating layer at the periphery of the electrode while eliminating or reducing the internal stress or thermal expansion coefficient of the insulating layer on the substrate. Warpage of the substrate can also be prevented.

Another aspect of the invention provides a circuit board including the semiconductor device described above. The circuit board has all advantages associated with the semiconductor device. An electronic apparatus including the circuit board is also provided. The electronic apparatus has all advantages described above.

### BRIEF DESCRIPTION OF THE DRAWINGS

The invention will be described with reference to the accompanying drawings, wherein like numbers reference like elements, and wherein:

FIG. 1 is a side cross-sectional view of an electrode of a semiconductor chip according to a first embodiment;

FIGS. 2A to 2C are diagrams for explaining a method for making the semiconductor chip according to the first embodiment;

FIGS. 3A and 3B are diagrams for explaining a method for making the semiconductor chip according to the first embodiment;

FIGS. 4A and 4B are diagrams for explaining a method for making the semiconductor chip according to the first embodiment;

FIGS. 5A and 5B are diagrams for explaining a method for making the semiconductor chip according to the first embodiment;

FIGS. 6A and 6B are diagrams for explaining a method for making the semiconductor chip according to the first embodiment;

FIG. 7 is a diagram for explaining a method for making the semiconductor chip according to the first embodiment;

FIG. 8 is a diagram for explaining stacking of semiconductor chips according to the first embodiment;

FIG. 9 is a diagram for explaining rewiring;

FIG. 10 is a diagram for explaining rewiring;

FIG. 11 is a diagram for explaining a circuit board;

FIG. 12 is a diagram for explaining a method for making a semiconductor chip according to a second embodiment;

FIG. 13 is a diagram for explaining a method for making the semiconductor chip according to a second embodiment; and

FIG. 14 is a perspective view of a cellular phone, which is an example of electronic apparatuses.

### DESCRIPTION OF THE EMBODIMENTS

The embodiments will now be described with reference to the drawings. In each drawing, individual components are depicted in various suitable scales so that the components are easily recognizable.

### First Embodiment

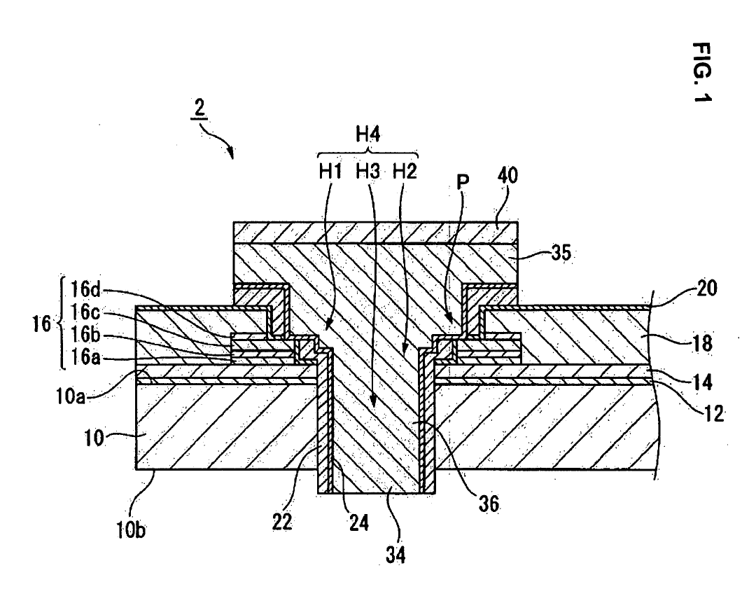

A semiconductor chip, which is a semiconductor device according to a first embodiment of the invention, will first described with reference to FIG. 1. FIG. 1 is a side cross-sectional view of an electrode of a semiconductor chip 2 according to the first embodiment. The semiconductor chip 2 includes a substrate 10 in which an integral circuit is formed, and an electrode 34. The electrode 34 is formed in a through hole H4 across an active face 10a and the rear face 10b of the substrate 10. A first insulating film 22 is disposed between the electrode 34 and the inner wall of the through hole H4.

[Semiconductor Device]

The semiconductor chip 2 shown in FIG. 1 has an integral circuit (not shown) constituted from electronic devices such as transistors, memory devices, and the like, on the surface 10a of the substrate 10 composed of silicon and the like. On the active face 10a of the substrate 10, an insulating film 12 composed of silicon oxide (SiO₂) or the like is disposed. On the surface of the insulating film 12, an interlayer insulating film 14 composed of borophosphosilicate glass (BPSG) is disposed. The thickness of the substrate 10 is, for example, about 625 μm.

An electrode pad 16 is disposed at a particular position of the surface of the interlayer insulating film 14. The electrode pad 16 is constituted from a first layer 16a composed of titanium and the like, a second layer 16b composed of titanium nitride (TiN) and the like, a third layer 16c composed of aluminum-copper (AlCu) and the like, and a fourth layer (cap layer) composed of TiN and the like. These four layers are stacked in that order from the bottom. The materials for the electrode pad 16 may be adequately changed depending on the electrical, physical, and chemical characteristics desired. In other words, the electrode pad 16 may be composed of only aluminum, which is commonly used in electrodes of integral circuit, or only copper, which has low electrical resistance.

In a plan view, the electrode pads 16 are aligned at the periphery of the semiconductor chips 2. Alternatively, the electrode pads 16 may be aligned at the central portion of the semiconductor chips 2. When the electrode pads 16 are aligned at the periphery, the electrode pads 16 are aligned parallel to at least one side (in many cases, two or four sides) of the semiconductor chip 2. Each electrode pad 16 is electrically connected to the integral circuit at positions not shown in the drawing. Please note that no integral circuit is formed under the electrode pads 16.

A passivation film 18 is disposed on the interlayer insulating film 14 to cover the electrode pad 16. The passivation film 18 is composed of SiO₂, SiN, a polyimide resin, or the like, and has a thickness of about 1 μm, for example.

At the central portion of the electrode pad 16, an opening H1 of the passivation film 18 and an opening H2 of the electrode pad 16 are formed. The diameter of the opening H2 is smaller than that of the opening H1 and is about 60 μm, for example. Moreover, in the fourth layer 16d of the electrode pad 16, an opening having the same diameter as that of the opening H1 is formed. A third insulating film 20 composed of SiO₂ is formed over the passivation film 18, the opening H1, and the inner wall of the opening H2.

At the central portion of the electrode pad 16, an opening H3 penetrating the third insulating film 20, the interlayer insulating film 14, the insulating film 12, and the substrate 10 is formed. The diameter of the opening H3 is smaller than that of the opening H2 and is about 30 μm, for example. The opening H3 may be, for example, circular or rectangular in shape in a plan view. The openings H1, H2, and H3 form the through hole H4 across the active face and the rear face. The depth of the through hole H4 is, for example, about 70 μm.

The first insulating film 22 covers the inner wall of the through hole H4 and the third insulating film 20 on the substrate 10. The first insulating film 22 on the third insulating film 20 is disposed at the periphery of the through hole H4. The third insulating film 20 is exposed in other regions. The third insulating film 20 and the first insulating film 22 at a particular portion of the surface of the third layer 16c of the electrode pad 16 near the periphery of the opening H2 are removed to electrically connect the electrode pad 16 to the electrode 34. The first insulating film 22 covering the inner wall of the through hole H4 projects from the rear face 10b of the substrate 10. The first insulating film 22 thereby functions as a protective film when an electrode terminal is disposed on the rear face of the substrate 10. The first insulating film 22 prevents current leakage, corrosion due to oxygen, moisture, etc., and the like and has a thickness of about 1 μm, for example.

On the particular portion of the surface of the third layer 16c mentioned above and the remaining first insulating film 22, a base film 24 is disposed. The base film 24 is constituted from a barrier layer (barrier metal) formed on the first insulating film 22 and the like, and a seed layer (seed electrode) on the barrier layer. The barrier layer prevents diffusion of the material of the base film 24 into the substrate 10 and is composed of, for example, TiW, TiN, or TaN. The seed layer acts as an electrode in forming the electrode 34 by plating described below and is composed of Cu, Au, Ag, or the like.

In the space defined by the base film 24, the electrode 34 is formed. The electrode 34 is composed of a conductive material, such as Cu or W, having a low electrical resistance. When the electrode 34 is composed of a conductive material, such as poly-Si doped with an impurity such as B or P, for example, the barrier layer is not needed since there is no longer a need for preventing diffusion of the material to the substrate 10. The electrode 34 formed in the through hole H4 has a plug portion 36. The plug portion 36 is electrically connected to the electrode pad 16 via the base film 24 at the portion P shown in FIG. 1. The lower face of the plug portion 36 is exposed to the exterior. The electrode 34 is also disposed above the passivation film 18 at the periphery of the opening H1, thereby forming a post portion 35. The post portion 35 may be circular or rectangular in shape in a plan view.

In the first embodiment, the plug portion 36 of the electrode 34 projects from the rear face of the substrate 10. The height of the portion of the plug portion 36 projecting from the rear surface is about 10 to 20 μm. With this structure, the gap between semiconductor chips can be secured when a plurality of semiconductor chips are stacked. Thus, it becomes easier to supply an underfill or the like to the gaps of the semiconductor chips. By adjusting the height of the projection of the plug portion 36, the distance between the semiconductor chips can be adjusted. In the event a thermosetting resin or the like, instead of the underfill, is applied on the rear face 10b of the semiconductor chip 2, the thermosetting resin or the like can be applied while avoiding the projecting plug portion 36. Thus, the interconnection between the semiconductor chips can be ensured.

On the upper face of the post portion 35 of the electrode 34, a solder layer 40 (bonding member) is formed. The solder layer 40 may be composed of a common PbSn alloy or the like but is preferably composed of a lead-free solder material such as an AgSn alloy from the ecological standpoint. Instead of the solder layer 40 composed of a soft solder, a hard solder (molten metal) layer composed of an SnAg alloy or the like or a metal paste layer composed of an Ag paste or the like may be formed. The hard solder layer and the metal paste layer are also preferably composed of lead-free materials from the ecological standpoint. The semiconductor chip 2 of this embodiment has the above-described structure.

Method for Making the Semiconductor Device

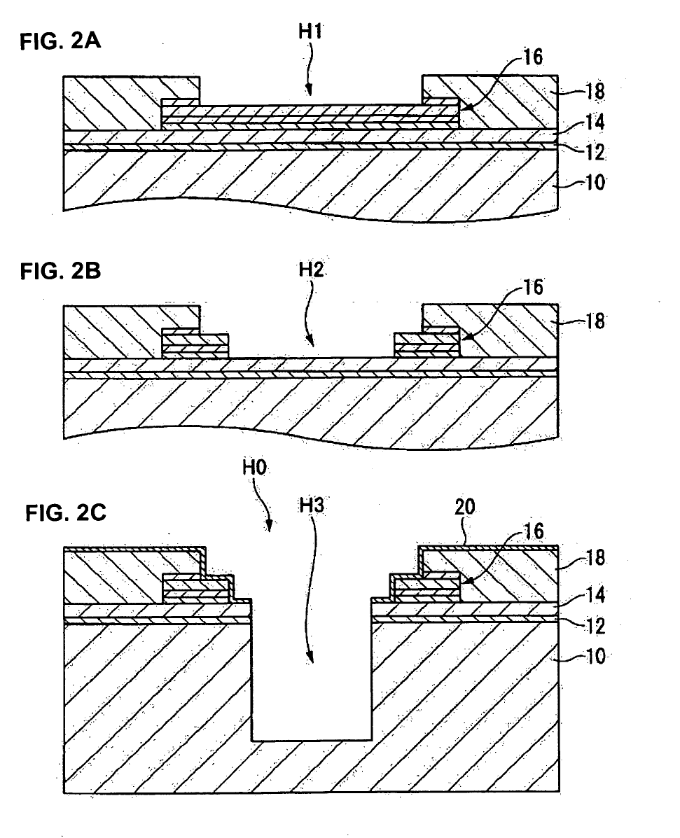

A method for making the semiconductor chip of this embodiment will now be described with reference to FIGS. 2A to 6B. FIGS. 2A to 6B are diagrams for explaining the method for making the semiconductor chip of this embodiment. Although the description below relates to simultaneous processing of a large number of semiconductor chip forming regions in a semiconductor substrate, the process below may be conducted on individual semiconductor chips.

Referring to FIG. 2A, the insulating film 12 is formed on the substrate 10, and the interlayer insulating film 14 is formed on the insulating film 12. The electrode pad 16 is then formed on the interlayer insulating film 14. In particular, the layers corresponding to the first to fourth layers of the electrode pad 16 are sequentially formed on the entire face of the interlayer insulating film 14 by sputtering or the like. A resist is applied on the top, and the target shape of the electrode pad 16 is patterned in the resist. Etching is conducted through the patterned resist acting as a mask to form an electrode pad having a predetermined shape (e.g., rectangular shape). The passivation film 18 is then formed on the electrode pad 16.

Next, the opening H1 is formed in the passivation film 18. In particular, a resist or the like is applied on the entire face of the passivation film. The resist may be a photoresist, electron beam resist, or X-ray resist, and may be a positive type or a negative type. The application of the resist is done by spin coating, dipping, spray coating, or the like. The applied resist is pre-baked, exposed through a mask having the pattern of the opening H1, developed to form the shape of the opening H1 in the resist, and post-baked.

The passivation film 18 is then etched using the patterned resist as a mask. In this embodiment, the passivation film 18 and the fourth layer of the electrode pad 16 is etched. The etching may be wet etching or dry etching but is preferably dry etching. The dry etching may be reactive ion etching (RIE). After the opening H1 is formed in the passivation film 18, the resist on the passivation film 18 is removed by a remover. As a result, the opening H1 is formed in the passivation film 18 to expose the electrode pad 16, as shown in FIG. 2A.

Referring now to FIG. 2B, the opening H2 is formed in the electrode pad 16. In particular, the entire face of the exposed electrode pad 16 and the passivation film 18 is covered with a resist, and the shape of the opening H2 is patterned in the resist layer. Using the patterned resist layer as a mask, the electrode pad 16 is dry-etched. The dry etching may be RIE. Subsequently, the resist layer is removed to form the opening H2 in the electrode pad 16, as shown in FIG. 2B.

Next the third insulating film 20 is formed over the top of the layers and the substrate 10. The third insulating film 20 functions as a mask in forming the hole H3 in the substrate 10 by dry etching. The thickness of the third insulating film 20 is adjusted to, for example, about 2 μm depending on the depth of the opening H3 to be formed in the substrate 10. Although the third insulating film 20 is composed of SiO₂ in this embodiment, the third insulating film 20 may be composed of a photoresist that can yield suitable selectivity ratio to Si. Alternatively, the third insulating film 20 may be composed of tetraethyl orthosilicate (Si(OC₂H₅)₄, hereinafter referred to as TEOS), formed by plasma-enhanced chemical vapor deposition (PECVD), hereinafter referred to as PE-TEOS, O₃-TEOS formed by thermal CVD using ozone, or silicon oxide formed by CVD.

Subsequently, the shape of the opening H3 is patterned in the third insulating film 20. In particular, a resist of the like is applied on the entire face of the third insulating film 20, and the shape of the opening H3 is patterned in the resist layer. Using the patterned resist as a mask, the third insulating film 20, the interlayer insulating film 14, and the insulating film 12 are dry-etched. The resist layer is then removed to form the pattern of the opening H3 in the third insulating film 20 and the like and to expose the substrate 10.

Next, the opening H3 is formed in the substrate 10 by high rate dry etching. The dry etching may be RIE or inductively coupled plasma (ICP) etching. During the etching, the third insulating film 20 (SiO₂) is used as the mask, as described above; instead, a resist layer may be used as the mask. The depth of the hole H3 is adequately controlled depending on the final thickness of the semiconductor chip. That is, the depth of the opening H3 is adjusted so that the tip of the electrodes formed in the opening H3 is exposed from the rear surface of the substrate 10 after the semiconductor chip is etched to the final target thickness. Thus, the opening H3 is formed in the substrate 10 as shown in FIG. 2C. The openings H1, H2, and H3 form a concavity H0 extending over the active face of the substrate 10 and the interior of the substrate 10.

Next, the first insulating film 22 is formed on the inner walls of the concavity H0 and the surface of the third insulating film 20. The first insulating film 22 is composed of PE-TEOS or O₃-TEOS, for example, and is formed by plasma TEOS or the like to have a thickness of about 1 μm. A resist 26 is then applied on the entire surface of the substrate 10 to cover the concavity H0. The resist may be applied by spin coating or the like. The resist layer is exposed through a mask having a pattern larger than the concavity H0 and developed. The exposed portion of the resist layer is removed with a solvent so that the unexposed portions remain to form a resist pattern. In other words, a resist layer larger than the concavity H0 covers the top of the concavity H0.

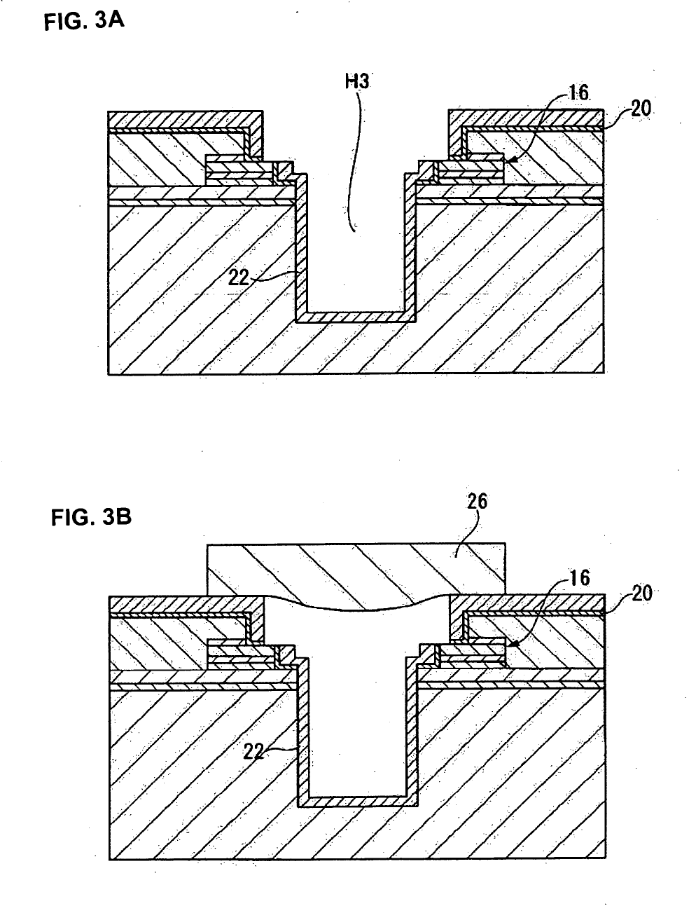

The first insulating film 22 and the third insulating film 20 are then anisotropically etched to expose part of the electrode pad 16. In this embodiment, part of the surface of the electrode pad 16 is exposed along the periphery of the opening H2. This is done by applying a resist or the like on the entire surface of the first insulating film 22, patterning the portion to be exposed, and anisotropically etching the first insulating film 22 and the third insulating film 20 using the patterned resist layer as a mask. The anisotropic etching is preferably dry etching, such as RIE. Thus, the composite shown in FIG. 3A is prepared.

A resist 26 is applied on the entire face of the first insulating film 22 covering the concavity H0 on the substrate 10. The resist 26 may be applied on the substrate 10 by spin coating, dipping, spray coating, or the like. Next, the resist 26 is exposed and developed to form a resist layer having a predetermined pattern. In particular, the resist 26 is exposed using a mask pattern having a circular shape corresponding to the shape of the concavity H0 and a diameter larger than 70 μm, which is the diameter of the concavity H0, to transfer the pattern on the resist layer. Then, in the development process, the exposed portion of the resist layer is removed with a solvent to leave the unexposed portions of the resist pattern. The resist 26 is pre-baked to form a patterned resist layer larger than the diameter of the opening H1, as shown in FIG. 3B.

The first insulating film 22 is dry etched using the patterned resist 26 prepared as in above. The dry etching is conducted with reactive ions that allow anisotropic etching. The RIE apparatus used for the etching is adjusted to a power of 200 W and a pressure of 0.3 Torr. First, 30 sccm of an activated species, i.e., the reaction product, CF4 is introduced into the RIE apparatus. A voltage was applied to the RIE apparatus to form a plasma of CF4. The plasma is adsorbed to the surface of the first insulating film 22 on the substrate 10 to carry out reaction and to synthesize a volatile reaction product thereby. The reaction product is then parted from the surface of the first insulating film 22 on the substrate 10 to carry out etching. Upon completion of the etching, the resist 26 is removed with a remover or the like. In this embodiment, the first insulating film 22 is substantially removed except in the peripheral region of the concavity H0.

Preferable reaction products on the surface of the first insulating film 22 are compounds such as CHF₃ and C₄F₈. It is also preferable to adjust the progress of the etching of the first insulating film 22 by adjusting the power and pressure of the RIE apparatus and the amount of the reaction product introduced in the RIE apparatus. For example, by increasing the power and decreasing the pressure of the RIE apparatus, larger amounts of the reaction product can be generated, and the overall etching rate can be increased as a result. Thus, the surface of the first insulating film 22 on the substrate 10 can be etched at a higher rate.

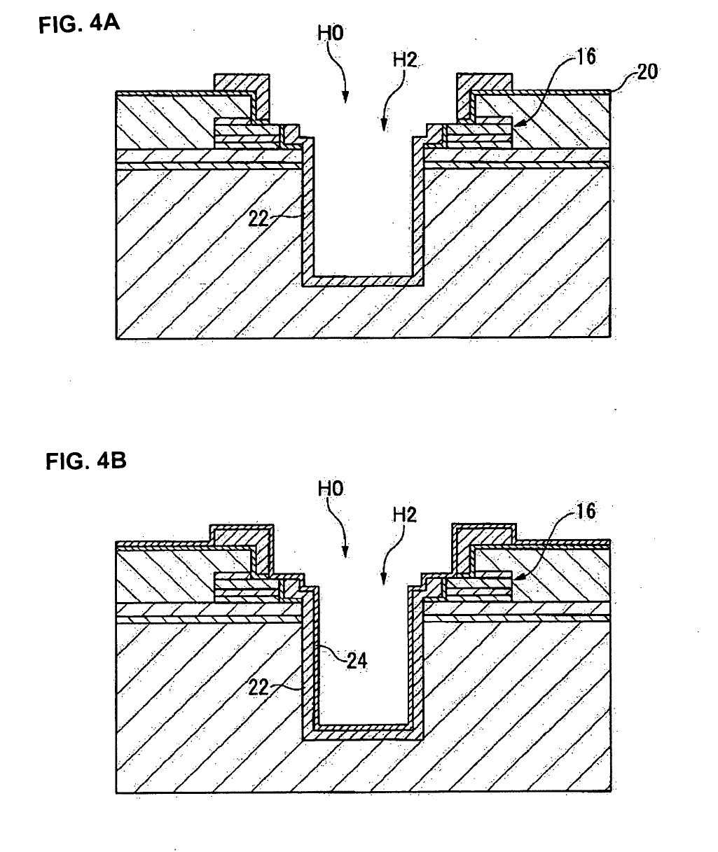

The base film 24 is then formed on the surfaces of the electrode pad 16, the first insulating film 22, and the associated components exposed by etching, as shown in FIG. 4B. The base film 24 is formed by forming a barrier layer first and then forming a seed layer on the barrier layer. The barrier and seed layers are formed by, for example, physical vapor deposition (PVD) such as vacuum vapor deposition, sputtering, or ion plating, chemical vapor deposition (CVD), ion metal plasma (IMP) deposition, or electroless plating.

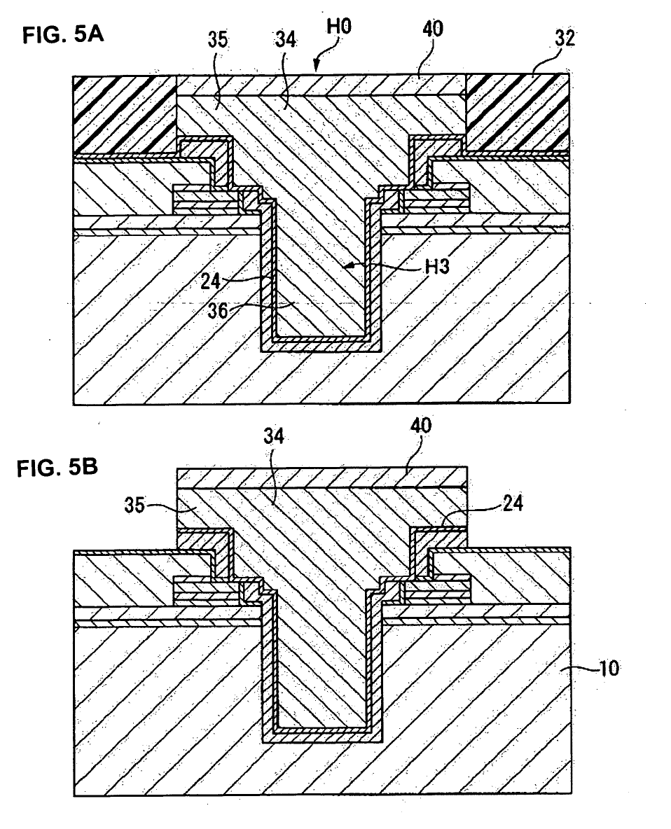

The electrode 34 is then formed, as shown in FIG. 5A. In particular, the electrode 34 is formed by applying a resist 32 over the substrate 10. The resist 32 may be a plating liquid resist or a dry film. Although a resist used to etch aluminum electrodes typically incorporated in semiconductor devices or an insulating resin resist may be used to form the electrode 34, the resist must have resistance to a plating solution or an etchant used in the subsequent step.

The application of the resist 32 is done by spin-coating, dipping, spray-coating, or the like. The thickness of the resist 32 is adjusted to a value approximately the same as the total of the height of the post portion 35 of the electrode 34 and the thickness of the solder layer 40. The resist 32 is then pre-baked.

The pattern having a planar shape of the post portion 35 of the electrode 34 is transferred onto the resist layer. In particular, the resist 32 is exposed and developed using a mask having a predetermined pattern. When the planar shape of the post portion 35 is rectangular, a pattern having a rectangular opening is transferred onto the resist 32. The size of the opening is adjusted according to the pitch of the electrodes 34 in the semiconductor chip and may be a 120 μm square or 80 μm square. The size of the opening is adjusted so that the resist 32 does not collapse after the patterning.

The above description is for the process of forming the resist 32 surrounding the post portion 35 of the electrode 34. However, the resist 32 does not have to surround the entire periphery of the post portion 35. For example, the resist 32 may be disposed on the left and right sides of the post portion 35 in the drawing of FIG. 5A and not on other portions. The resist 32 is disposed along at least one side of the shape of the periphery of the post portion 35.

The above description is for the process of forming the resist 32 by photolithography. However, according to this technique, the resist may be trapped inside the opening H3 during the course of applying the resist, and the resist may remain inside the opening H3 even after the development. It is therefore preferable to use a dry film or to employ a printing technique, such as screen-printing, to form a resist 32 already having a pattern. Alternatively, a droplet discharger, such as an inkjet device, may be used to discharge the droplets of the resist on the desired portions only to form the resist 32. In this manner, a patterned resist 32 can be formed without the resist entering the opening H3.

Using the resist 32 as a mask, the concavity H0 is filled with an electrode material to form the electrode 34. The filling of the electrode material is conducted by plating, CVD, or the like. An example of the plating is electrochemical plating (ECP). During the plating, the seed layer of the base film 24 is used as the electrode. Furthermore, a cup-type plating machine is used as the plating device. A cup-type plating machine has a cup-shaped vessel from which a plating solution is discharged to conduct plating. In this manner the concavity H0 is filled with the electrode material to form the plug portion 36 the opening in the resist 32 is also filled with the electrode material to form the post portion 35.

Next, the solder layer 40 is formed on the top of the electrode 34. The solder layer 40 is formed by a printing technique, such as solder plating or screen plating. The seed layer of the base film 24 may be used as an electrode for solder plating. A cup-type plating machine may be used as a plating device. Instead of the solder layer 40, a hard solder layer composed of SnAg or the like may be formed. The hard solder layer may be formed by plating or printing. The state after the plating is shown FIG. 5A.

The resist 32 is removed with a remover. An example of the remover is ozone water. The base film 24 exposed at the top of the substrate 10 is then removed. In particular, a resist or the like is applied over the substrate 10, and the shape of the post portion 35 of the electrode 34 is transferred to the resist. Using the resulting patterned resist as a mask, the base film 24 is dry-etched. When a hard solder layer is formed instead of the solder layer 40, the base film 24 may be etched using the hard solder layer as a mask. In such a case, the process can be simplified since no photolithographic step is necessary. The structure shown in FIG. 5B is thus formed.

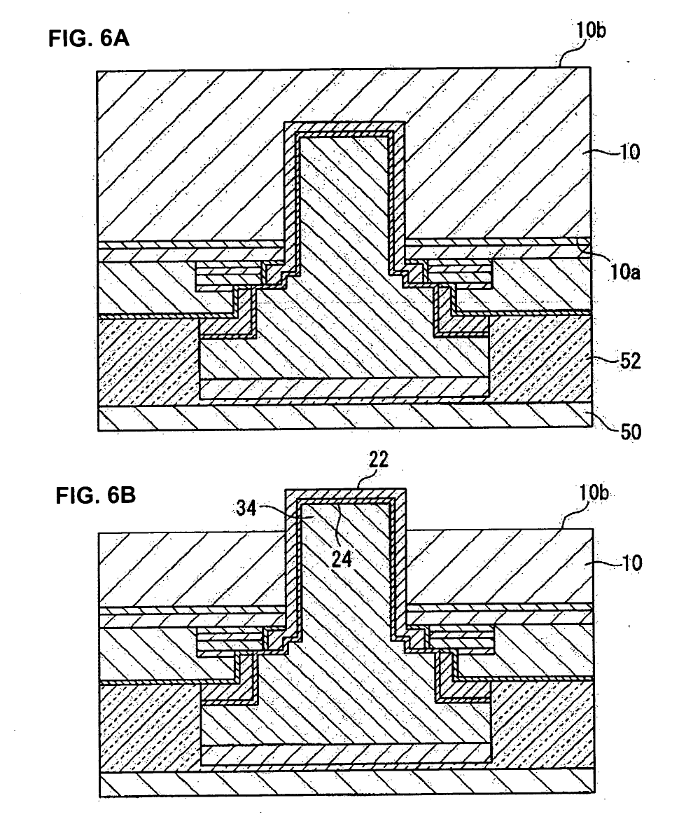

Next, the substrate 10 is flipped upside down. A reinforcing member 50 is attached to the bottom of the substrate 10, as shown in FIG. 6A. The reinforcing member 50 may be a protective film or the like but is preferably a hard material, such as glass. In this manner, the substrate 10 is prevented from cracking or the like during working of the rear face 10b of the substrate 10. The reinforcing member 50 is attached to the substrate 10 using an adhesive 52 or the like. The adhesive 52 is preferably a curable adhesive such as a thermosetting adhesive or photocurable adhesive. In this manner, the reinforcing member 50 can be tightly bonded to the substrate 10 regardless of the irregularities in the active face 10a of the substrate 10. When a photocurable adhesive, such as an UV curable adhesive, is used as the adhesive 52, it is preferable to use a transparent reinforcing member 50 composed of glass or the like. The adhesive can be easily cured by irradiation from outside the reinforcing member 50.

Next, as shown in FIG. 6B, the rear face 10b of the substrate 10 is etched to expose the tip of the first insulating film 22. The tip of the electrode 34 is projected from the rear face 10b of the substrate 10. The etching technique may be wet or dry. The process time can be reduced by performing etching after roughly polishing the rear face 10b of the substrate 10 to expose the tip. Furthermore, the first insulating film 22 and the base film 24 can be etched at the same time with the substrate 10.

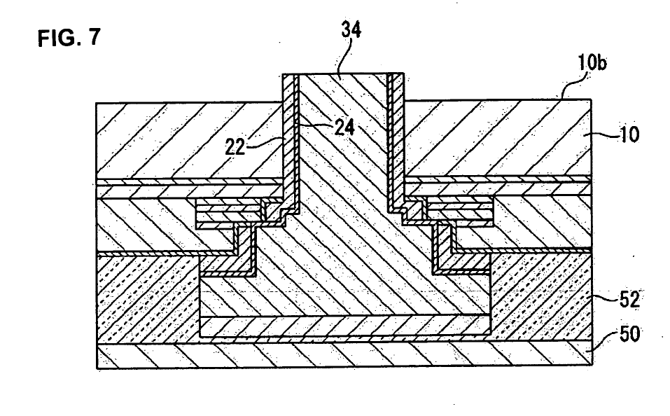

Next, the tip of the electrode 34 is exposed, as shown in FIG. 7. In particular, the first insulating film 22 and the base film 24 are removed to expose the tip of the electrode 34. The first insulating film 22 and the base film 24 are removed by chemical mechanical polishing (CMP). CMP is a process of polishing a substrate by mechanical polishing using polishing cloth and by chemical interaction between the substrate and a polishing solution supplied on the substrate. The tip of the electrode 34 may be polished at the same time with removing the first insulating film 22 and the base film 24 by polishing. In this manner, the base film 24 can be completely removed, and the conduction failure between electrodes of the stacked semiconductor chips can be prevented.

Subsequently, the adhesive 52 is dissolved with a solvent or the like to detach the reinforcing member 50 from the substrate 10. A dicing tape (not shown in the drawing) is attached to the rear face 10b of the substrate 10, and the substrate 10 is diced to form individual semiconductor chips. Here, the substrate 10 may be cut by CO₂ or YAG laser irradiation. The semiconductor chip 2 shown in FIG. 1 according to the present embodiment is thus formed.

Multilayer Structure

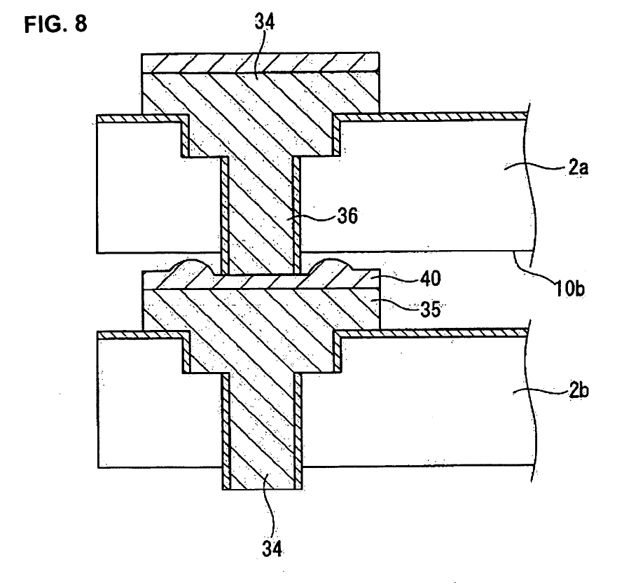

The semiconductor chips 2 formed as above are stacked to form a three-dimensionally mounted semiconductor composite. FIG. 8 is a side cross-sectional view of stacked semiconductor chips (2a and 2b). The semiconductor chips 2a and 2b are disposed so that the top face of the electrode 34 of the semiconductor chip 2b at the lower side is in contact with the bottom face of the plug portion of the electrode 34 of the semiconductor chip 2a at the upper side. The electrodes 34 of the semiconductor chips 2a and 2b are connected to each other via the solder layer 40. In particular, the semiconductor chips 2a and 2b are pressed while melting the solder layer 40 by reflow. In this manner, a solder alloy is formed at the junction of the electrodes 34 and the solder layer 40 so that the electrodes 34 are mechanically and electrically connected to each other. Thus, the semiconductor chips 2a and 2b are interconnected to each other. If necessary, an underfill material may be supplied in the gaps between the stacked semiconductor chips.

Rewiring

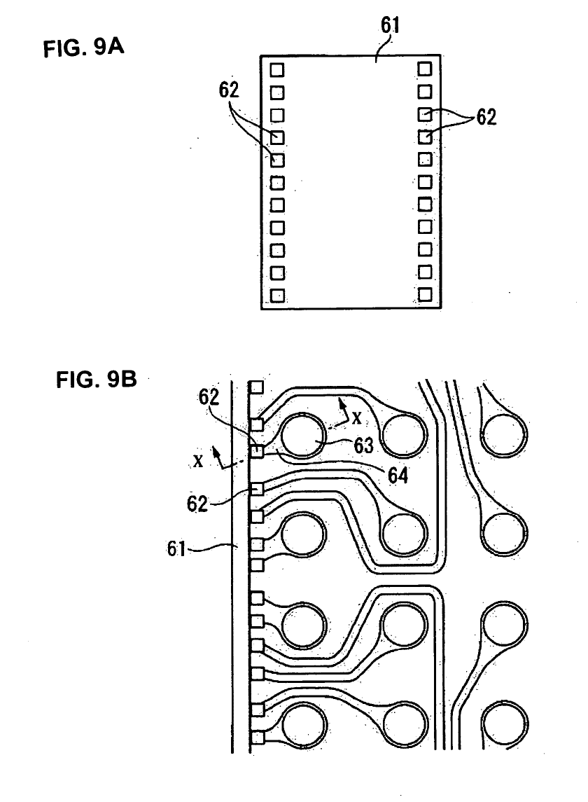

Rewiring is preferably performed to mount a multilayer semiconductor device prepared as above onto a circuit board. First, the importance of the rewiring is briefly described. FIGS. 9A and 9B are diagrams for explaining rewiring of the semiconductor chips. Electrodes 62 are formed on a surface of a semiconductor chip 61 along two opposing sides of the chip 61, as shown in FIG. 9A. The interelectrode pitch is thus small. If such a semiconductor chip 61 is mounted onto a circuit board, short-circuiting may occur between neighboring electrodes. In order to increase the interelectrode pitch, the electrodes 62 formed along the opposing sides of the semiconductor chip 61 are rewired to extract electrodes at the central portion of the semiconductor chip.

FIG. 9B is a plan view of a rewired semiconductor chip 61. Circular electrode pads 63 are formed at the central portion of the semiconductor chip 61 to form a matrix. Each electrode pad 63 is connected to one or more electrodes 62 by rewiring 64. In this manner, the electrodes are extracted at the central portion to increase the interelectrode pitch.

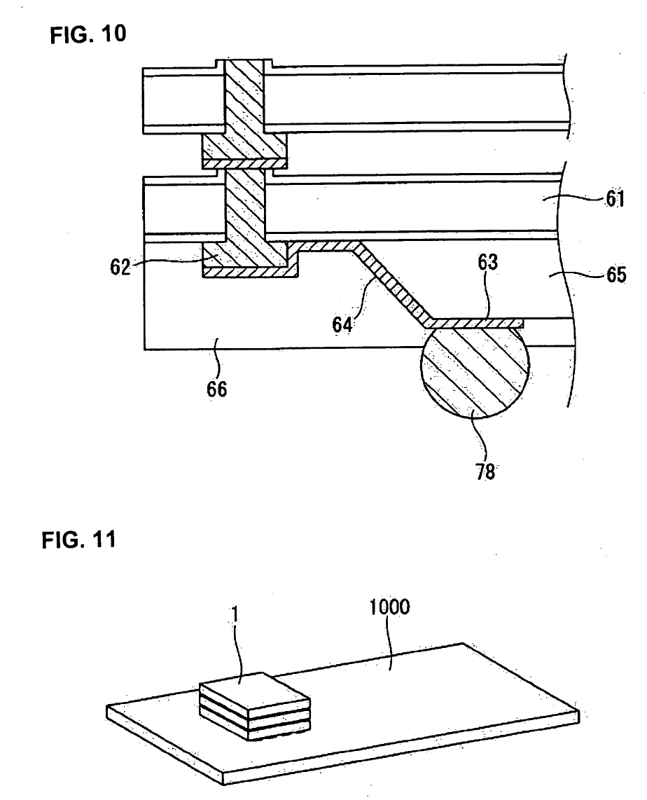

FIG. 10 is a side cross-sectional view taken along line X-X in FIG. 9B. The multilayer semiconductor device formed as above is flipped upside down. A solder resist 65 is disposed at the central portion of the bottom of the bottommost semiconductor chip 61. The rewiring 64 extends from the post portion of the electrode 62 to the solder resist 65. The electrode pad 63 is formed at the end of the rewiring 64 close to the solder resist 65. A bump 78 is formed on the electrode pad. The bump 78 is, for example, a solder bump, and may be formed by printing or the like. The entire bottom face of the semiconductor chip 61 is covered with a resin 66 for reinforcement.

Circuit Board

FIG. 11 is a perspective view of a circuit board. A semiconductor device 1 constituted from a plurality of semiconductor chips is mounted onto a circuit board 1000. In particular, the semiconductor device 1 is mounted onto the surface of the circuit board 1000 via a bump of the bottommost semiconductor chip of the semiconductor device 1 by reflow, flip chip bonding (FCB), or the like. The semiconductor device 1 may be mounted onto the circuit board with an isotropic conductive film between the semiconductor device 1 and the circuit board.

### Second Embodiment

In the first embodiment, the first insulating film 22 is etched before the electrode 34 is formed in the concavity H0. In the second embodiment, the first insulating film 22 is etched after the electrode 34 is formed in the concavity H0. The second embodiment will now be described with reference to the drawings. The descriptions of the steps identical to the first embodiment are omitted to avoid redundancy.

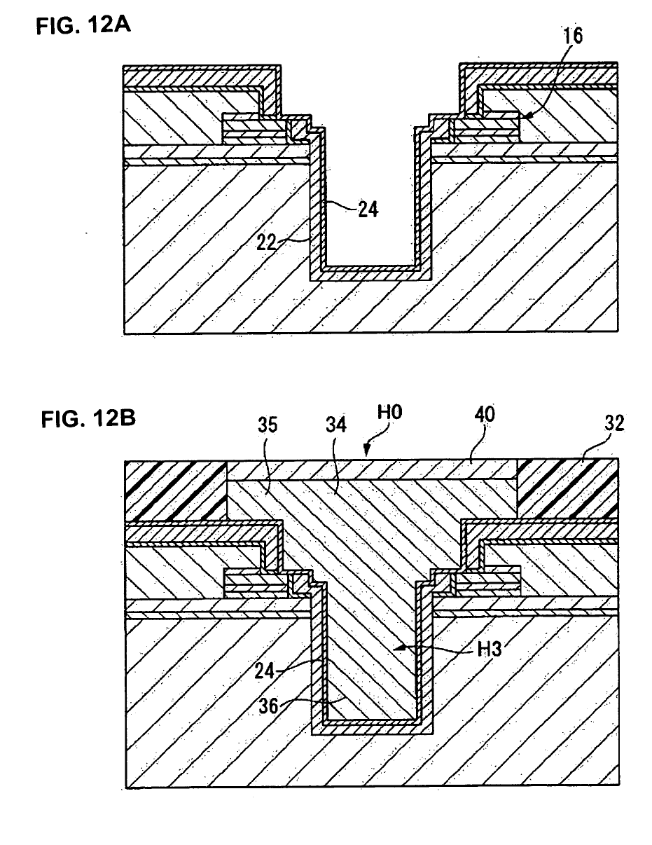

The first insulating film 22 is formed on the substrate 10 by the steps shown in FIGS. 2A to 3A. Then, the base film 24 is formed to cover the surface of the electrode pad 16 and the first insulating film 22, as shown in FIG. 12A. Thus, this embodiment differs from the first embodiment in which the first insulating film 22 is etched before the formation of the base film 24. In the second embodiment, the base film 24 is formed by the same technique as described in the first embodiment.

Next, the electrode 34 shown in FIG. 12B is formed. In particular, a resist 32 is applied on the base film 24, and a predetermined shape, such as a circle or rectangle, is formed in the resist. The electrode 34 is then formed by plating. Specific techniques of plating are the same as those described in the first embodiment.

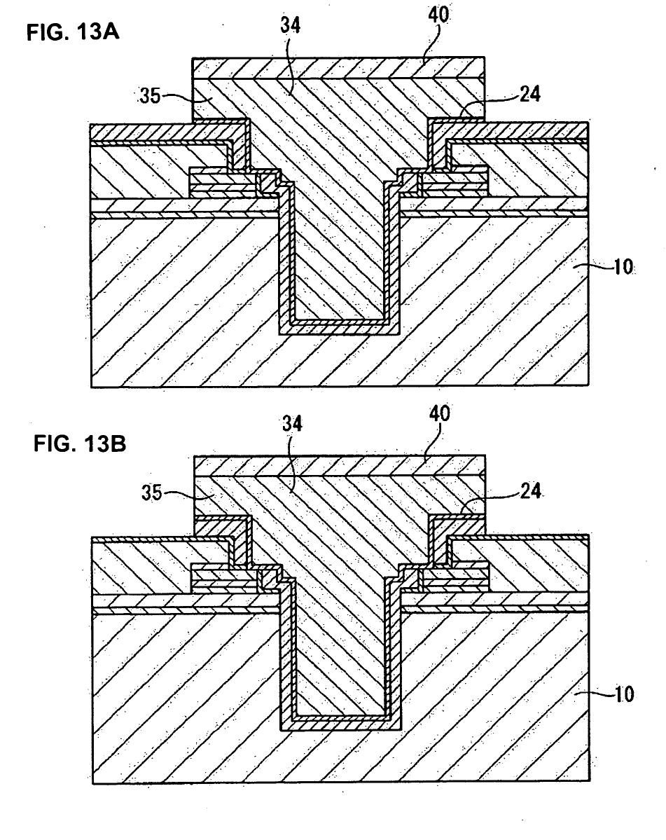

Subsequently, the solder layer 40 is formed on the electrode 34, as shown in FIG. 13A. The specific techniques of forming the solder layer 40 are the same as those described in the first embodiment. Referring now to FIG. 13B, the first insulating film 22 and the base film 24 are simultaneously etched using the solder layer 40 as a mask. The first insulating film 22 is etched by the technique described in the first embodiment. The steps shown in FIGS. 6A, 6B, and 7 are performed to obtain the semiconductor chip 2.

In the second embodiment, the first insulating film 22 is etched using the solder layer 40 as a mask. As is previously described, the solder layer 40 electrically connects the electrodes 34 of the semiconductor chips 2 to each other when the semiconductor chips 2 are stacked. Thus, the first insulating film 22 is etched by utilizing one step of the process of producing the semiconductor device 1, and a step of patterning a resist by photolithography can be omitted. Thus, the time required for production can be reduced. Since the electrode 34 is covered by the solder layer 40, the etchant does not come into direct contact with the electrode 34. Thus, it becomes possible to prevent the electrode 34 from being removed by the etchant.

Electronic Apparatus

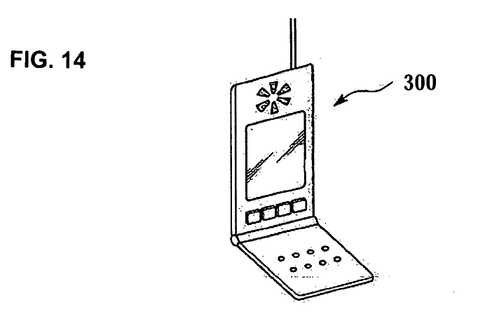

An embodiment of the electronic apparatus incorporating the semiconductor device described above will now be described with reference to FIG. 14. FIG. 14 is a perspective view of a cellular phone 300. The semiconductor device is inside the casing of the cellular phone 300.

The semiconductor device may be applied to various other electronic apparatuses. For example, the semiconductor device may applied to liquid crystal projectors, multimedia personal computers (PCs) and engineering working stations (EWSs), pagers, word processors, televisions, view-finder and monitor-direct video tape recorders, electronic notebooks, electronic desk calculators, car navigation systems, POS terminals, and devices with touch panels.

The technical scope of the invention is not limited to the embodiments described above and includes various modifications and alternations without departing from the spirit of the invention. For example, in the first embodiment, the resist 26 having a predetermined pattern is formed by photolithography and this resist 26 is used as a mask to etch the first insulating film 22. Instead, it is possible to directly etch the first insulating film 22 without using the resist 26 as a mask. In particular, the anisotropic etching may be performed by adjusting the etching rate of the first insulating film 22 on the substrate 10 to be higher than the etching rate of the first insulating film 22 inside the concavity H0 to be lower. In this manner, the first insulating film 22 can be etched without requiring any mask. The etching may be of a wet-type, dry-type, or the like. In this manner, the first insulating film 22 on the substrate 10 can be etched while leaving the first insulating film 22 inside the concavity H0. Moreover, since the photolithographic step can be omitted, the time required for production can be reduced, and the production process can be simplified.

In the first and second embodiments, the first insulating film 22 at the periphery of the concavity H0 is completely removed. However, it is also preferable not to remove all of the first insulating film 22 at the periphery but to reduce the thickness of the first insulating film 22 at the periphery of the electrode 34. According to this structure, the internal stress and the thermal expansion coefficient of the first insulating film 22 on the substrate 10 can be minimized, and warpage of the substrate 10 can be prevented when the substrate 10 is assembled into a chip.

1. A method for making a semiconductor device having an electrode penetrating a substrate, the method comprising:
(a) forming a concavity in an active face of the substrate;
(b) forming an insulating layer on the active face of the substrate and the interior of the concavity;
(c) removing at least part of the insulating layer formed outside the concavity;
(d) forming the electrode by filling the interior of the concavity with a conductor; and
(e) exposing the electrode from a rear face of the substrate opposite to the active face by milling the substrate from the rear face side,
wherein (a) to (e) are performed in that order.

2. The method according to claim 1, wherein, in (c), the insulating layer is etched while covering the concavity with a mask.

3. The method according to claim 1, wherein, in (c), the entire face of the insulating layer is etched while adjusting the etching rate of the insulating layer formed on the substrate to be higher than the etching rate of the insulating layer formed on the interior of the concavity in the substrate.

4. A method for making a semiconductor device having an electrode penetrating a substrate, the method comprising:
(f) forming a concavity in an active face of the substrate;
(g) forming an insulating layer on the active face of the substrate and interior of the concavity;
(h) forming the electrode by filling the interior of the concavity with a conductor;
(i) removing at least a portion of the insulating layer outside the concavity; and
(j) exposing the electrode from a rear face of the substrate opposite to the active face by milling the substrate from the rear face side,
wherein (f) to (j) are performed in that order.

5. The method according to claim 4, wherein, in (i), the insulating layer is etched while covering the concavity with a mask.

6. The method according to claim 1, wherein, in (i), the insulating layer is etched while covering the concavity with a bonding member

7. A semiconductor device comprising:
a substrate having an active face including an integrated circuit, a rear face, and a hole penetrating the substrate from the active face to the rear face;
an insulating layer disposed on the active face of the substrate and on an inner wall of the hole; and
an electrode disposed inside the space defined by the insulating layer, the electrode being exposed from the rear face,
wherein a portion of the insulating layer on the active face of the substrate has a thickness smaller than the thickness of a portion of the insulating layer at the periphery of the electrode.

8. A semiconductor device comprising:
a substrate having an active face including an integrated circuit, a rear face, and a hole penetrating the substrate from the active face to the rear face;
an insulating layer disposed on an inner wall of the hole; and
an electrode disposed inside the space defined by the insulating layer, the electrode being exposed from the rear face.

9. A circuit board comprising the semiconductor device according to claim 8.

10. An electronic apparatus comprising the circuit board according to claim 9.
